(19) United States
(12) Patent Application Publication
(10) Pub. No.: US 2013/0043457 A1
(43) Pub. Date: Feb. 21, 2013

(54) LIGHT EMITTING DEVICE

(71) Applicants: Dong Hun KANG, Seoul (KR); Sang Hyun Lee, Seoul (KR); Sung Yi Jung, Seoul (KR); Jong Pil Jeong, Seoul (KR)

(72) Inventors: Dong Hun KANG, Seoul (KR); Sang Hyun Lee, Seoul (KR); Sung Yi Jung, Seoul (KR); Jong Pil Jeong, Seoul (KR)

(21) Appl. No.: 13/459,635

(22) Filed: Apr. 30, 2012

(30) Foreign Application Priority Data
Aug. 16, 2011 (KR) 10-2011-0081347

(51) Int. Cl. H01L 33/04

(52) U.S. Cl. 257/13; 257/E33.005

(57) ABSTRACT

Provided are a light emitting device, a method of manufacturing the same, a light emitting device package, and a lighting system. The light emitting device includes: a first conductive semiconductor layer; a superlattice layer on the first conductive semiconductor layer; an active layer on the superlattice layer; and a second conductive semiconductor layer on the active layer. The superlattice layer comprises InₓGa₍₁₋ₓ₎N(0<x<1) doped with an n-type dopant and undoped In_{y}Ga_{(1-y)}N(0<y<1).

### CROSS-REFERENCE TO RELATED APPLICATIONS

This application claims under 35 U.S.C. §119 to Korean Patent Application No. 10-2011-0081347, filed Aug. 16, 2011, which is hereby incorporated by reference in its entirety.

### BACKGROUND

The present disclosure relates to a light emitting device, a method of manufacturing a light emitting device, a light emitting device package, and a lighting system.

The Light Emitting Device (LED) is a device that is characterized in converting electrical energy into light energy, and for example, is capable of providing various colors by adjusting a composition ratio of compound semiconductors.

An LED market increasingly requires higher performance of the LED. Additionally, its cost aspect becomes very important as much as its characteristics.

Furthermore, VF (operating voltage), light intensity, and reliability are important items in an LED used as a Back Light Unit (BLU). Moreover, its chip size becomes smaller to improve the performance, and also injection current (or voltage) becomes higher.

In addition, since a rated voltage of the LED is constant even if its chip size is reduced, a current density of the chip is increased. At this point, a junction temperature is increased due to high current, thereby deteriorating electrical characteristics of the chip. As a result, its life cycle becomes shortened; VF is increased; and device efficiency is drastically decreased.

Additionally, according to a related art, if an LED has no tolerance to Electro Static Discharge (ESD), a zener diode is inserted into a package (PKG) to protect the LED. However, due to this zener diode, PKG light intensity of about 5% is lost and also PKG manufacturing cost is also increased.

Moreover, according to a related art, a process loss also occurs due to a process for mounting the zener diode, so that ESD improvement is required at an Epi/Chip terminal.

### SUMMARY

Embodiments provide a light emitting device having improved an operating voltage, reliability, and light intensity, a method of manufacturing the light emitting device, a light emitting package, and a lighting system.

Embodiments provide a light emitting device having improved ElectroStatic Discharge (ESD) characteristics, a method of manufacturing the light emitting device, a light emitting package, and a lighting system.

In one embodiment, a light emitting device includes: a first conductive semiconductor layer; a superlattice layer on the first conductive semiconductor layer; an active layer on the superlattice layer; and a second conductive semiconductor layer on the active layer, wherein the superlattice layer comprises InₓGa₍₁₋ₓ₎N(0<x<1) doped with an n-type dopant and undoped In_{y}Ga_{(1-y)}N(0<y<1).

According to an embodiment of the present invention, provide are a light emitting device having improved an operating voltage, reliability, and light intensity, a method of manufacturing the light emitting device, a light emitting package, and a lighting system.

Additionally, according to an embodiment of the present invention, provide are a light emitting device having improved ESD characteristics, a method of manufacturing the light emitting device, a light emitting package, and a lighting system.

The details of one or more embodiments are set forth in the accompanying drawings and the description below. Other features will be apparent from the description and drawings, and from the claims.

### BRIEF DESCRIPTION OF THE DRAWINGS

FIG. 1 is a sectional view of a light emitting device according to an embodiment.

FIGS. 2A, 2B, and 2C are views illustrating configuration examples of a strain control layer of a light emitting device according to an embodiment.

FIGS. 3A to 3C are views illustrating ESD characteristic improvement of a light emitting device according to an embodiment.

FIG. 3D is a view illustrating ESD characteristics of a light emitting device according to a related art.

FIG. 4 is a sectional view of a light emitting device according to an embodiment.

FIG. 5 is a perspective view of a lighting unit according to an embodiment.

FIG. 6 is a perspective view of a backlight unit according to an embodiment.

### DETAILED DESCRIPTION OF THE EMBODIMENTS

Reference will now be made in detail to the embodiments of the present disclosure, examples of which are illustrated in the accompanying drawings.

Hereinafter, a light emitting device, a light emitting device package, and a lighting system will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

### Embodiment

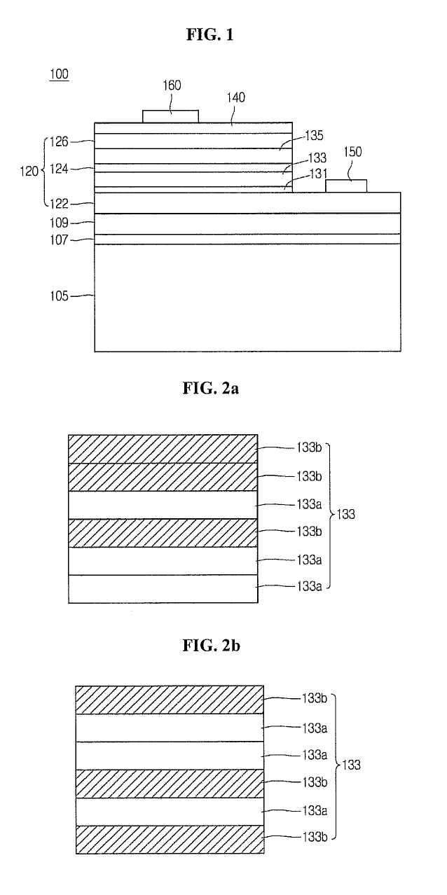

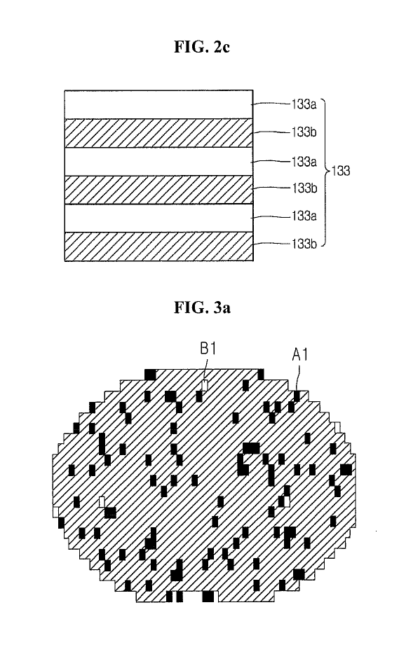

FIG. 1 is a sectional view of a light emitting device 100 according to an embodiment. FIGS. 2A, 2B, and 2C are views illustrating examples of configuration of a strain control layer 133 in a light emitting device according to an embodiment. In an embodiment, the strain control layer 133 may be a superlattice layer. Accordingly, the strain control layer 133 may be a superlattice strain control layer 133 in this embodiment, but is not limited thereto.

FIG. 1 illustrates a lateral type light emitting device exemplary, but an embodiment is not limited thereto. That is, a vertical type light emitting device may be applied to an embodiment.

The light emitting device 100 may include a first conductive semiconductor layer 122, a superlattice layer 133 on the first conductive semiconductor layer, an active layer 124 on the superlattice layer 133, and a second conductive semiconductor layer 126 on the active layer 124.

The substrate 105 includes a conductive substrate or an insulating substrate. For example, the substrate may be formed of at least one of Al₂O₃, SiC, Si, GaAs, GaN, ZnO, GaP, InP, Ge, and Ga₂0₃. An uneven structure such as a Patterned Sapphire Substrate (PSS) may be formed on the substrate 105, and the present invention is not limited thereto.

A buffer layer 107 may be formed on the substrate 105. The buffer layer 107 may alleviate the lattice mismatch between a material and the substrate 105 of the light emitting structure, and a material of the buffer layer is a Group III-V compound semiconductor, for example, at least one of GaN, InN, AlN, InGaN, AlGaN, InAlGaN, and AlInN but is not limited thereto.

According to an embodiment, an undoped GaN layer 109 may be formed on the buffer layer 107. The undoped GaN layer may be formed with a thickness that allows an uneven on the substrate to be planarized, and may improve quality of a GaN light emitting structure 120, which is formed during the following process through the undoped GaN layer 109.

A light emitting structure 120 may be formed on the undoped GAN layer 109. The light emitting structure 120 may include a first conductive semiconductor layer 122, an active layer 124, and a second conductive semiconductor layer 126.

The first conductive semiconductor layer 122 may be formed of a Group III-V compound semiconductor doped with a first conductive dopant. If the first conductive semiconductor layer 122 is an N-type semiconductor layer, the first conductive dopant may include Si, Ge, Sn, Se, Te as an N-type dopant, but is not limited thereto.

The first conductive semiconductor layer 122 may include a semiconductor material having an empirical formula of InₓAl_{y}Ga_{1-x-y}N (0≦x≦1, 0≦y≦1, 0≦x+y≦1), but is not limited thereto. For example, the first conductive semiconductor layer 122 may be formed of at least one of GaN, InN, AlN, InGaN, AlGaN, InAlGaN, AlInN, AlGaAs, InGaAs, AlInGaAs, GaP, AlGaP, InGaP, AlInGaP, and InP.

The first conductive semiconductor layer may form an N-type GaN layer through Chemical Vapor Deposition (CVD), Molecular Bean Epitaxy (MBE), sputtering, or Hydride Vapor Phase Epitaxy (HYPE). Additionally, the first conductive semiconductor layer 122 may be formed by injecting SiH₄ including an n-type dopant such as TMGa, NH₃, N₂, and Si into a chamber.

According to an embodiment, an alleviation layer 131 may be further included between the superlattice layer 133 and the first conductive semiconductor layer 122.

The alleviation layer may have an empirical formula of InₐGa₁₋ₐN/In_{b}Ga_{1-b}N (if and only if, 0≦a≦1, 0≦b≦1), but is not limited thereto.

Embodiments provide a light emitting device having improved an operating voltage, reliability, and light intensity, a method of manufacturing the light emitting device, a light emitting package, and a lighting system.

Additionally, embodiments provide a light emitting device having improved ESD characteristics, a method of manufacturing the light emitting device, a light emitting package, and a lighting system.

For this, according to an embodiment, the superlattice layer 133 may be formed on the first conductive semiconductor layer 122.

FIGS. 2A to 2C are views illustrating examples of configuration of the superlattice layer 133 in the light emitting device of FIG. 1. Referring to FIGS. 2A to 2C, the superlattice layer 133 may include InₓGa₍₁₋ₓ₎N(0<x<1) 133b doped with an n-type dopant, and undoped In_{y}Ga_{(1-y)}N(0<y<1) 133a. According to an embodiment, the n-type dopant doped InₓGa₍₁₋ₓ₎N(0<x<1) 133b and undoped In_{y}Ga_{(1-y)}N(0<y<1) 133a may be alternately stacked, but are not limited thereto. According to an embodiment, the n-type dopant doped InₓGa₍₁₋ₓ₎N(0<x<1) 133b and undoped In_{y}Ga_{(1-y)}N(0<y<1) 133a may not be alternately stacked, but may be randomly disposed.

For example, as shown in FIG. 2A, the superlattice structure 133 includes a stack structure including first to sixth layers. The first, second, and fourth layers are the undoped In_{y}Ga_{(1-y)}N(0<y<1) 133a, and the third, fifth, and sixth layers are the n-type dopant doped InₓGa₍₁₋ₓ₎N(0<x<1) 133b.

Additionally, as shown in FIG. 2B, the superlattice structure 133 includes a stack structure including first to sixth layers. The second, fourth, and fifth layers are the undoped In_{y}Ga_{(1-y)}N(0<y<1) 133a, and the first, third, and sixth layers are the n-type dopant doped InₓGa₍₁₋ₓ₎N(0<x<1) 133b.

Moreover, as shown in FIG. 2C, the superlattice structure 133 includes a stack structure including first to sixth layers. The second, fourth, and sixth layers are the undoped In_{y}Ga_{(1-y)}N(0<y<1) 133a, and the first, third, and fifth layers are the n-type dopant doped InₓGa₍₁₋ₓ₎N(0<x<1) 133b.

A composition ratio x of In may be 0<x<0.18 in the n-type dopant doped InₓGa₍₁₋ₓ₎N(0<x<1) 133b. Additionally, the composition ratio x of In may be 0<x<0.18 in the n-type dopant doped InₓGa₍₁₋ₓ₎N(0<x<1) 133b may be lower than that of a well in the active layer 124 formed later. Accordingly, the superlattice structure 133 may be a non light emitting layer unlike the active layer 124.

A composition ratio y of In may be 0<y<x in the undoped In_{y}Ga_{(1-y)}N(0<y<1) 133a. For example, the composition ratio x in the n-type dopant doped InₓGa₍₁₋ₓ₎N(0<x<1) 133b may be about four or five times than that y in the undoped In_{y}Ga_{(1-y)}N(0<y<1) 133a. accordingly, a mutual lattice constant difference is repeatedly given, so that strain due to lattice mismatch between the first conductive semiconductor layer 122 and the active layer formed later may be alleviated by repetition of tensile stress and compressive stress.

Moreover, a thickness of the n-type dopant doped InₓGa₍₁₋ₓ₎N(0<x<1) 133b may be about four or five times than that of the undoped In_{y}Ga_{(1-y)}N(0<y<1) 133a. Stain due to lattice mismatch between the first conductive semiconductor layer 122 and the active layer formed later may be alleviated. Also, the thicknesses of the n-type dopant doped InₓGa₍₁₋ₓ)N(0<x<1) 133b and the undoped In_{y}Ga_{(1-y)}N(0<y<1) 133a may be controlled by adjusting a composition ratio of In or a processing time, but are not limited thereto.

According to an embodiment, the n-type dopant doped InₓGa₍₁₋ₓ₎N(0<x<1) 133b and undoped In_{y}Ga_{(1-y)}N(0<y<1) 133a may have a superlattice structure having at least six periods.

According to an embodiment, as the n-type dopant doped InₓGa₍₁₋ₓ₎N(0<x<1) 133b and the undoped In_{y}Ga_{(1-y)}N(0<y<1) 133a may be repetitively stacked in at least six periods, more electrons gather at a low energy level of the active layer. As a result, recombination probability of electrons and holes is increased so that light emitting efficiency may be improved.

According to an embodiment, the n-type dopant doped InₓGa₍₁₋ₓ₎N(0<x<1) 133b and undoped In_{y}Ga_{(1-y)}N(0<y<1) 133a may be alternately stacked, but are not limited thereto.

According to an embodiment, the undoped In_{y}Ga_{(1-y)}N(0<y<1) 133a between the n-type dopant doped InₓGa₍₁₋ₓ₎N(0<x<1) 133b may be formed, so that current may be easily distributed in a parallel direction (i.e., perpendicular to a stacking direction). Accordingly, current dispersion effect is maximized, and tolerance to occurring ESD may be increased.

According to an embodiment, the n-type dopant may be Si, and a doping concentration of Si may be about 3×10¹⁸ atoms/cm³ to about 3×10¹⁹ atoms/cm³. For example, a doping concentration of Si may be about 3×10¹⁸ atoms/cm³ to about 5×10¹⁸ atoms/cm³, but is not limited thereto.

If the doping concentration of Si is less than the lower limit, Si does not properly contribute to current spread, and if the doping concentration of Si exceeds the upper limit (3×10¹⁹ atoms/cm³), Si serves as an impurity in an active layer, so that it may give bad influence on limit emission of the active layer.

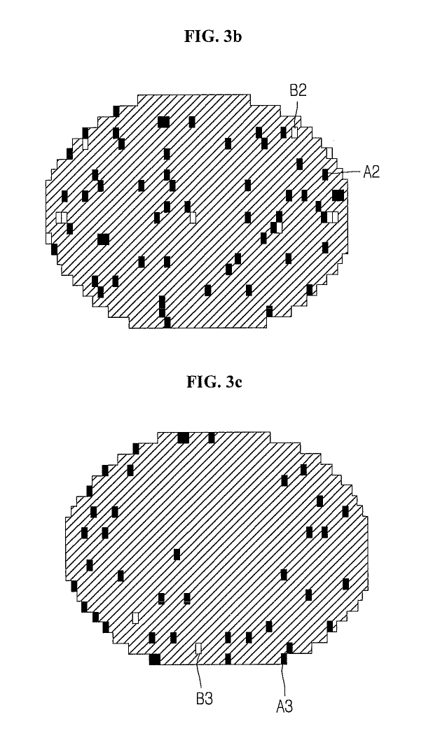

FIGS. 3A to 3C are views illustrating examples of improved ESD characteristics according to an embodiment. Additionally, FIG. 3D is a view illustrating an example of ESD characteristic in a related art light emitting device.

According to embodiments, ESD characteristics are improved compared to a related art as shown in Table 1 below.

TABLE 1

| | FIG. 3a (first | FIG. 3b (second | FIG. 3c (third | Related |
|---|---|---|---|---|
| | embodiment) | embodiment) | embodiment) | art |
| ESD | 91% | 93% | 94% | 49% |
| characteristic | | | | |
| (Yield) | | | | |

FIG. 3A is a view illustrating an example of ESD characteristic improvement when −2 KV is applied three times with a configuration of the superlattice layer 133 of FIG. 2A according to an embodiment. FIG. 3B is a view illustrating an example of ESD characteristic improvement when −2 KV is applied three times with a configuration of the superlattice layer 133 of FIG. 2B according to an embodiment.

FIG. 3A illustrates an example of ESD characteristic improvement when −2 KV is applied three times with a configuration of the superlattice layer 133 of FIG. 2A according to an embodiment. The references A1, A2, A3 and A4 on the FIGS. 3A to 3D show damaged chip areas and, the references B1, B2, B3 and B4 show none-chip areas.

Additionally, FIG. 3D illustrates an example of ESD characteristic improvement when −2 KV is applied three times to a related art light emitting device.

According to an embodiment, ESD characteristics are improved by about 90% compared to a related art as shown in Table 1.

According to an embodiment, provide are a light emitting device having improved ESD characteristics, a method of manufacturing the light emitting device, a light emitting package, and a lighting system.

Again, referring to FIG. 1, an active layer 124 is formed on the superlattice layer 133 later.

The active layer 124 emits a light, which has an energy determined by a material-specific energy band of the active layer (for example, a light emitting layer) after combining electrons (injected through the first conductive semiconductor layer 122) and holes (injected through the second conductive semiconductor layer 126).

The active layer 124 may have at least one of a single quantum well structure, a Multi Quantum Well (MQW) structure, a quantum-wire structure, and a quantum dot structure. For example, the active layer 124 may have the MQW structure by injecting TMGa, NH3, N2, and TMIn, but is not limited thereto.

A well layer/barrier layer of the active layer 124 may have a pair structure with at least one of InGaN/GaN, InGaN/InGaN, GaN/AlGaN, InAlGaN/GaN, GaAs(InGaAs)/AlGaAs, and GaP(InGaP)/AlGaP, but is not limited thereto. The well layer may be formed of a material having a bandgap, which is lower than that of the barrier layer.

According to an embodiment, an electron blocking layer 135 may be formed on the active layer 124 in order to provide electron blocking and MQW cladding of the active layer 124. As a result, light emitting efficiency may be improved. For example, the electron blocking layer 135 may be formed of an AlₓIn_{y}Ga_{(1-x-y)}N(0≦x≦1,0≦y≦1) based semiconductor. Also, the electron blocking layer 135 may have a higher energy band than the active layer 124, and may be formed with a thickness of about 100 Å to about 600 Å but is not limited thereto.

Moreover, the electron blocking layer 135 may be formed of an Al_{z}Ga_{(1-z)}N/GaN(0≦z≦1) based superlattice, but is not limited thereto.

The electron blocking layer 135 may effectively block overflowing electrons after being ion-injected with a p-type, and may increase injection efficiency of holes. For example, the electron blocking layer 135 may effectively block overflowing electrons after Mg is ion-injected with a concentration range of 10¹⁸/cm³ to 10²⁰/cm³, and may increase injection efficiency of holes.

The second conductive semiconductor layer 126 may include a Group III-V compound semiconductor doped with a second conductive dopant, for example, a semiconductor material having an empirical formula of InₓAl_{y}Ga_{1-x-y}N(0≦x≦1, 0≦y≦1, 0≦x+y≦1). If the second conductive semiconductor layer 126 is a p-type semiconductor layer, the second conductive dopant may include Mg, Zn, Ca, Sr, and Ba as a p-type dopant.

The second conductive semiconductor layer 126 may be formed by injecting (EtCp₂Mg){Mg(C₂H_{5C}₅H₄)₂} including a p-type dopant such as TMGa, NH₃, N₂, and Mg into a chamber, so that a p-type GaN layer is formed, but is not limited thereto.

According to an embodiment, the first conductive semiconductor layer 122 may be realized with an n-type semiconductor layer, and the second conductive semiconductor layer 126 may be realized with a p-type semiconductor layer, but they are not limited thereto. Moreover, a semiconductor having an opposite polarity to the second conductive type, for example, an n-type semiconductor layer (not shown), may be formed on the second conductive semiconductor layer 126. Accordingly, the light emitting structure 120 may be realized with at least one of an N—P junction structure, a P—N junction structure, an N—P—N junction structure, and a P—N—P junction structure.

According to an embodiment, after mesa etching is performed to expose a portion of the first conductive semiconductor layer 122, a transmissive ohmic layer 140 may be formed on the second conductive semiconductor layer 126. For example, the transmissive ohmic layer 140 may be formed of at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO Nitride (IZON), Al—Ga ZnO (AGZO), In—Ga ZnO (IGZO), ZnO, IrOx, RuOx, NiO, RuOx/ITO, Ni/IrOx/Au, and Ni/IrOx/Au/ITO, but is not limited thereto.

Then, a first electrode 150 may be formed on the exposed first conductive semiconductor layer 122, and a second electrode 160 may be formed on the transmissive ohmic layer 140, respectively. The first electrode 150 and the second electrode 160 may be formed of a high conductive material such as Ni, Ti, Cr, and Au, but are not limited thereto.

According to an embodiment, provide are a light emitting device having improved an operating voltage, reliability, and light intensity, a method of manufacturing the light emitting device, a light emitting package, and a lighting system.

Additionally, according to an embodiment, provide are a light emitting device having improved ESD characteristics, a method of manufacturing the light emitting device, a light emitting package, and a lighting system.

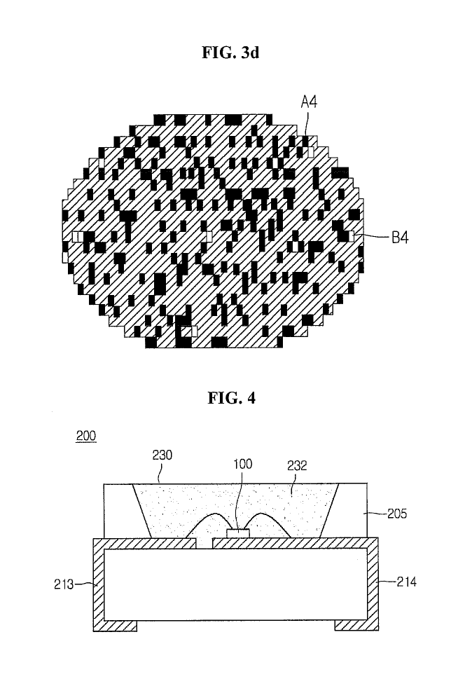

FIG. 4 is a view of a light emitting device package 200 with a light emitting device according to embodiments.

The light emitting device package 200 includes a package main body part 205, a third electrode layer 213 and a fourth electrode layer 214 in the main body part 205, a light emitting device 100 installed at the main body part 205 and electrically connected to the third electrode layer 213 and the fourth electrode layer 214, and a molding member 230 surrounding the light emitting device 100.

The main body part 205 may be formed of silicon material, synthetic resin material, or metal material, and an inclined plane may be formed around the light emitting device 100.

The third electrode layer 213 and the forth electrode layer 214 are electrically separated from each other, and serve to provide power to the light emitting device 100. Additionally, the third electrode layer 213 and the fourth electrode layer 214 may serve to increase light efficiency by reflecting the light generated from the light emitting device 100, and may also serve to exhaust the heat generated from the light emitting device 100 to the external.

The light emitting device 100 may have a lateral type shown in FIG. 1, but is not limited thereto. That is, the light emitting device 100 may have a vertical type also.

The light emitting device 100 may be installed on the package main body part 205, or installed on the third electrode layer 213 or the fourth electrode layer 214.

The light emitting device 100 may be electrically connected to the third electrode layer 213 and/or the fourth electrode layer 214 through a wire type, a flip chip type, or a die bonding type. According to an embodiment, the light emitting device 100 is electrically connected to the third electrode layer 213 and the forth electrode layer 214 through a wire, but is not limited thereto.

The molding member 230 may surround the light emitting device 100 to protect it. Additionally, since the molding member 230 includes a fluorescent substance 232, it may change the wavelength of light emitted from the light emitting device 100.

A plurality of light emitting device packages are arrayed on a substrate, an optical member on a path of light emitted from the light emitting device package, for example, a light guide plate, a prism sheet, a diffusion sheet, and a fluorescent sheet, may be disposed on the substrate. This light emitting device package, substrate, and optical member may serve as a backlight unit or a lighting unit. For example, the lighting system may include a backlight unit, a lighting unit, a pointing device, a lamp, and a streetlight.

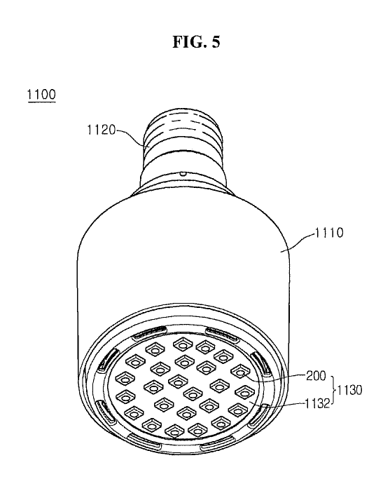

FIG. 5 is a perspective view of a lighting unit 1100 according to an embodiment. However, the lighting unit 1100 of FIG. 5 is just one example of a lighting system, but is not limited thereto.

According to an embodiment, the lighting unit 1110 may include a case main body 1110, a light emitting module 1130 at the case main body 1110, and a connection terminal 1120 at the case main body 1210 to receive power from an external power supply unit.

The case main body 1110 may be formed of a material having excellent heat dissipation characteristic, for example, a metal material or a resin material.

The light emitting module 1130 may include a substrate 1132 and at least one light emitting device package 200 mounted on the substrate 1132.

The substrate 1132 may be formed with a circuit pattern printed on an insulator, and may include a typical Printed Circuit Board (PCB), a metal core PCB, a flexible PCB, a flexible PCB, and a ceramic PCB.

Additionally, the substrate 1132 may be formed of a material that efficiently reflects light or may have the surface whose color efficiently reflects light such as white or silver.

At least one light emitting device package 200 may be mounted on the substrate 1132. Each light emitting device package 200 may include at least one Light Emitting Diode (LED) 100. The LED may include a colored LED emitting each colored light of red, green, blue or white, and an UltraViolet (UV) LED emitting UV.

The light emitting module 1130 may be disposed to have various configurations of light emitting device packages 200 to obtain color and brightness. For example, in order to obtain a high Color Rendering Index (CRI), a white LED, a red LED, and a green LED may be combined and disposed.

The connection terminal 1120 is electrically connected to the light emitting module 1130 so that power may be supplied to the light emitting module 1130. According to an embodiment, the connection terminal 1120 is screwed into and coupled to an external power in a socket type, but is not limited thereto. For example, the connection terminal 1120 having a pin may be inserted into an external power or may be connected to an external power through wiring.

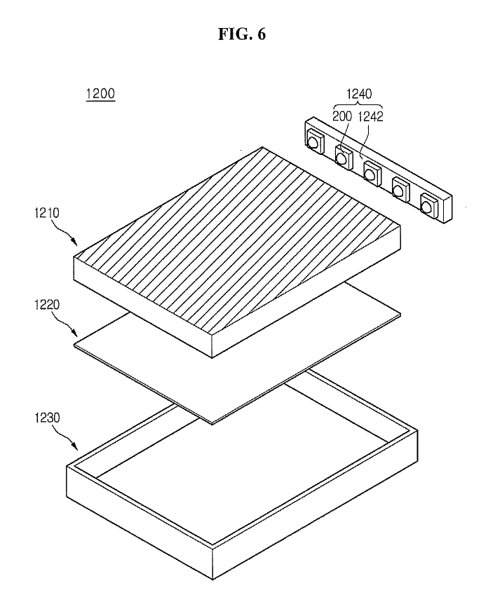

FIG. 6 is an exploded perspective view of a backlight unit according to an embodiment. However, the backlight unit 1200 of FIG. 6 is just one example of a lighting system, but is not limited thereto.

The backlight unit 1200 according to an embodiment may include a light guide plate 1210, a light emitting module 1240 providing light to the light guide plate 1210, a reflective member 1220 below the light guide plate 1210, and a bottom cover 1230 receiving the light guide plate 1210, the light emitting module 1240, and the reflective member 1220, and is not limited thereto.

The light guide plate 1210 may serve as a plane light source by diffusing light. The light guide plate 1210 may be formed of a transparent material, and may include one of an acrylic resin base such as polymethyl metaacrylate (PMMA), and polyethylene terephthlate (PET), poly carbonate (PC), cycloolefin copolymer (COC) and polyethylene naphthalate (PEN) resins.

The light emitting module 1240 provides light to at least one lateral side of the light guide plate 1210, and ultimately serves as a light source of a display device having the backlight unit installed.

The light emitting module 1240 may contact the light guide plate 1210, but is not limited thereto. In more detail, the light emitting module 1240 may include a substrate 1242 and a plurality of light emitting device packages 200 mounted on the substrate 1242. The substrate 1242 may contact the light guide plate 121, but is not limited thereto.

The substrate 1242 may be a PCB including a circuit pattern (not shown). However, the substrate 1242 may include a Metal Core PCB (MCPCB) and a Flexible PCB (FPCB) in addition to a typical PCB, but is not limited thereto.

Moreover, in relation to the plurality of light emitting device packages 200, a light emitting surface that emits light may be mounted spaced a predetermined distance from the light guide plate 1210.

The reflective member 1220 may be formed below the light guide plate 1210. The reflective member 1220 may improve the brightness of the back light unit by reflecting light incident to the bottom side of the light guide plate 1210 toward the top direction. The reflective member 1220 may be formed of PET, PC, and PVC resins, but is not limited thereto.

The bottom cover 1230 may receive the light guide plate 1210, the light emitting module 1240, and the reflective member 1220. For this, the bottom cover 1230 may be formed with a box form whose top surface is opened, but is not limited thereto.

The bottom cover 1230 may be formed of a metal material or a resin material, and may be manufactured through a process such as press molding or extrusion molding.

According to an embodiment, provide are a light emitting device having improved an operating voltage, reliability, and light intensity, a method of manufacturing the light emitting device, a light emitting package, and a lighting system.

Additionally, according to an embodiment, provide are a light emitting device having improved ESD characteristics, a method of manufacturing the light emitting device, a light emitting package, and a lighting system.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a first conductive semiconductor layer;
a superlattice layer on the first conductive semiconductor layer;
an active layer on the superlattice layer; and
a second conductive semiconductor layer on the active layer,
wherein the superlattice layer comprises InₓGa₍₁₋ₓ₎N(0<x<1) doped with an n-type dopant and undoped In_{y}Ga_{(1-y)}N(0<y<1).

2. The light emitting device according to claim 1, wherein a composition ratio of In in the InₓGa₍₁₋ₓ₎N(0<x<1) doped with an n-type dopant is 0<x<0.18.

3. The light emitting device according to claim 2, wherein a composition ratio y of In in the undoped In_{y}Ga_{(1-y)}N(0<y<1) is 0<y<x.

4. The light emitting device according to claim 1, wherein the superlattice layer has a superlattice structure wherein the InₓGa₍₁₋ₓ₎N(0<x<1) doped with an n-type and the undoped In_{y}Ga_{(1-y)}N(0<y<1) are disposed in more than or equal to six periods.

5. The light emitting device according to claim 1, wherein the InₓGa₍₁₋ₓ₎N(0<x<1) doped with an n-type and the undoped In_{y}Ga_{(1-y)}N(0<y<1) are alternately stacked.

6. The light emitting device according to claim 5, wherein when the InₓGa₍₁₋ₓ₎N(0<x<1) doped with an n-type and the undoped In_{y}Ga_{(1-y)}N(0<y<1) are alternately stacked, the undoped In_{y}Ga_{(1-y)}N(0<y<1) is disposed as an odd numbered layer and the InₓGa₍₁₋ₓ₎N(0<x<1) doped with an n-type is disposed as an even numbered layer.

7. The light emitting device according to claim 6, wherein the superlattice structure has a stack structure of first to sixth layers;
the second, fourth, and sixth layers are the undoped In_{y}Ga_{(1-y)}N(0<y<1); and
the first, third, and fifth layers are the InₓGa₍₁₋ₓ₎N(0<x<1) doped with an n-type.

8. The light emitting device according to claim 1, wherein the InₓGa₍₁₋ₓ₎N(0<x<1) doped with an n-type and the undoped In_{y}Ga_{(1-y)}N(0<y<1) are irregularly stacked.

9. The light emitting device according to claim 8, wherein the superlattice structure has a stack structure of first to sixth layers;
the first, second, and fourth layers are the undoped In_{y}Ga_{(1-y)}N(0<y<1); and
the third, fifth, and sixth layers are the InₓGa₍₁₋ₓ₎N(0<x<1) doped with an n-type.

10. The light emitting device according to claim 1, wherein the n-type dopant comprises Si.

11. The light emitting device according to claim 10, wherein a doping concentration of Si is 3×10¹⁸ atoms/cm³ to 3×10¹⁹ atoms/cm³.

12. The light emitting device according to claim 1, further comprising an alleviation layer between the superlattice layer and the first conductive semiconductor layer.

13. The light emitting device according to claim 1, wherein the superlattice layer is a non light emitting layer.

14. The light emitting device according to claim 13, wherein a composition ratio x of In in the InₓGa₍₁₋ₓ₎N(0<x<1) doped with an n-type is lower than that in a well of the active layer.

15. The light emitting device according to claim 14, wherein the composition ratio x of In in the InₓGa₍₁₋ₓ₎N(0<x<1) doped with an n-type is about four or five times than that y in the undoped In_{y}Ga_{(1-y)}N(0<y<1).

16. The light emitting device according to claim 1, wherein the InₓGa₍₁₋ₓ₎N(0<x<1) doped with an n-type and the undoped In_{y}Ga_{(1-y)}N(0<y<1) have respectively different thicknesses.

17. The light emitting device according to claim 16, wherein the thickness of the InₓGa₍₁₋ₓ₎N(0<x<1) doped with an n-type is about four or five times than that of the undoped In_{y}Ga_{(1-y)}N(0<y<1).

18. The light emitting device according to claim 16, wherein the thickness of the undoped In_{y}Ga_{(1-y)}N(0<y<1) comprises respectively different thicknesses of a plurality of updoped In_{y}Ga_{(1-y)}N(0<y<1).
